(19) United States
(12) Patent Application Publication
(10) Pub. No.: US 2024/0038481 A1
(43) Pub. Date: Feb. 1, 2024

(54) IMAGING, PROCESSING, AND/OR ANALYZING AN OBJECT USING A PARTICLE BEAM DEVICE

(71) Applicant: Carl Zeiss Microscopy GmbH, Jena (DE)

(72) Inventor: Josef Biberger, Wildenberg (DE)

(73) Assignee: Carl Zeiss Microscopy GmbH, Jena (DE)

(21) Appl. No.: 18/204,593

(22) Filed: Jun. 1, 2023

(30) Foreign Application Priority Data
Jun. 2, 2022 (DE) 10 2022 113 918.2

(51) Int. Cl. H01J 37/09; H01J 37/073; H01J 37/08; H01J 37/147

(52) U.S. Cl. CPC H01J 37/09; H01J 37/073; H01J 37/08; H01J 37/1471; H01J 37/28

(57) ABSTRACT

Imaging, processing and/or analyzing an object using a particle beam device includes guiding a first particle beam over the object, processing the object using the first particle beam or detecting first interaction particles and/or a first interaction radiation, where the first interaction particles and/or the first interaction radiation results/result from an interaction of the first particle beam with the object, controlling a second deflection device for guiding the second particle beam over the object even while the first particle beam is being guided over the object, and deflecting the first particle beam from the object. Only when the first particle beam has been deflected, the object is processed using the second particle beam or detecting second interaction particles and/or a second interaction radiation that results/result from an interaction of the second particle beam with the object.

### CROSS-REFERENCE TO RELATED APPLICATIONS

This application claims the priority of the German patent application No. 10 2022 113 918.2, filed on Jun. 2, 2022, which is incorporated herein by reference.

### TECHNICAL FIELD

This application relates to imaging, processing and/or analyzing an object using a particle beam device having a particle beam with charged particles.

### BACKGROUND

Electron beam devices, in particular a scanning electron microscope (also referred to as SEM below) and/or a transmission electron microscope (also referred to as TEM below), are used to examine objects (samples) in order to obtain knowledge with respect to the properties and the behavior under specific conditions.

In an SEM, an electron beam (also referred to as primary electron beam below) is generated using a beam generator and focused onto an object to be examined by way of a beam guiding system. The primary electron beam is guided over a surface of the object to be examined by way of a deflection device. Here, the electrons of the primary electron beam interact with the object to be examined. Interaction particles and/or interaction radiation is/are generated as a result of the interaction. As interaction particles, electrons, in particular, are emitted by the object (so-called secondary electrons) and electrons of the primary electron beam are backscattered (so-called backscattered electrons) at the object. The secondary electrons and backscattered electrons are detected by a particle detector and used for image generation. An image representation of the object to be examined is thus obtained. In particular, x-ray radiation and/or cathodoluminescence arises as interaction radiation. The interaction radiation is detected with a radiation detector and is used to analyze the object, in particular.

In the case of a TEM, a primary electron beam is likewise generated using a beam generator and directed onto an object to be examined using a beam guiding system. The primary electron beam passes through the object to be examined. When the primary electron beam passes through the object to be examined, the electrons of the primary electron beam interact with the material of the object to be examined. The electrons passing through the object to be examined are imaged onto a luminescent screen or onto a detector (for example a camera) by a system consisting of an objective and a projection unit. Here, imaging can also take place in the scanning mode of a TEM. Usually, such a TEM is referred to as STEM. Additionally, provision can be made for detecting electrons backscattered at the object to be examined and/or secondary electrons emitted by the object to be examined using a further detector in order to image an object to be examined.

Furthermore, it is known from the prior art to use combination devices for examining objects, wherein both electrons and ions can be guided onto an object to be examined. By way of example, it is known to additionally equip an SEM with an ion beam column. An ion beam generator arranged in the ion beam column is used to generate ions that are used for preparing an object (for example ablating material of the object or applying material to the object) or for imaging. The SEM serves here in particular for observing the preparation, but also for further examination of the prepared or unprepared object.

It is known from the prior art that in the aforementioned combination device, the primary electron beam provided by the SEM and the ion beam provided by the ion beam column are guided simultaneously onto the object. The intention is, for example, to generate images of the object using the primary electron beam and, at the same time, to generate images of the object using the ion beam. As an alternative, it is known to process the object using the ion beam. At the same time, the processing of the object is intended to be observed using the primary electron beam of the SEM. However, if both the primary electron beam and also the ion beam are supplied at the same time, disturbing influences arise which might influence the imaging. For example, electrostatic and/or magnetic fields that can influence the beam path of the ion beam of the ion beam device are generated by the objective lens of the SEM. Additionally or alternatively, electrostatic and/or magnetic fields that can influence the beam path of the primary electron beam of the SEM are generated by the objective lens of the ion beam device. Moreover, if the primary electron beam and the ion beam are supplied at the same time, it is difficult to differentiate during the detection of the interaction particles whether interaction particles are caused due to an interaction of the object with the primary electron beam or with the ion beam. Imaging and/or analyzing the object with a differentiation according to interaction particles arising from an interaction of the object with the primary electron beam or from an interaction of the object with the ion beam are/is therefore made more difficult.

In order to reduce the disturbing influences when using a first particle beam (for example the primary electron beam) and a second particle beam (for example the ion beam), three methods are known from the prior art, which are explained below.

In the first known method, one of the two aforementioned particle beams is switched off and the respective other of the two aforementioned particle beams is guided to the object. Accordingly, the objective lens of the switched-off particle beam is controlled such that disturbing influences for the other particle beam are reduced. The other particle beam is then used to generate images of the object or to process the object. However, it is disadvantageous here that both the imaging of the object with a sufficient detection of interaction particles and/or interaction radiation and also the adequate processing of the object take longer than when both aforementioned particle beams are guided to the object simultaneously. Moreover, the one particle beam is possibly switched off at an unfavorable point in time. For example, if the ion beam is used to ablate material of the object such that due to the force of gravity the object bends in such a way that the object should actually be fastened to a holder, then switching off the ion beam too late can result in the object being destroyed.

In the second known method, neither of the two aforementioned particle beams is switched off. Rather, both the first particle beam (for example the primary electron beam) and also the second particle beam (for example the ion beam) are simultaneously guided to the object and scanned over the object. For scanning the first particle beam, a first scan parameter set is used to control a first scanning unit for scanning the first particle beam. By contrast, for scanning the second particle beam, a second scan parameter set is used to control a second scanning unit for scanning the second particle beam. The first scan parameter set and the second scan parameter set differ from one another. The aforementioned scan parameter sets include scan parameters for controlling the respective scanning unit. For example, the dwell time of the respective particle beam at a location of the object, the scanning speed of the respective particle beam, and the scanning direction of the respective particle beam are used as scan parameters. The aim of this known procedure is to statistically distribute the disturbing influences occurring in the images of the object in the images of the object. However, it has been found that, as a result, the first particle beam and the second particle beam are typically used to generate images of the object that have a poorer quality than images that are generated when one of the two aforementioned particle beams is switched off and when the other of the two aforementioned particle beams is used to generate the images of the object.

In the third known method, again neither of the two aforementioned particle beams is switched off. Rather, both the first particle beam (for example the primary electron beam) and also the second particle beam (for example the ion beam) are simultaneously guided to the object. The second particle beam is used to process the object. The first particle beam, on the other hand, is used to observe the processing of the object. To observe using the first particle beam, a first control parameter set for controlling units of the particle beam device is used. For processing the object using the second particle beam, on the other hand, a second control parameter set for controlling units of the particle beam device is used. The first control parameter set and the second control parameter set differ from one another. The aforementioned control parameter sets include parameters for guiding the respective particle beam over the object. For example, control parameters used are the current of the respective particle beam, control currents and/or control voltages of the objective lens for the respective particle beam, and control currents and/or control voltages of the deflection units for the respective particle beam. However, it has been found that the disturbing influences are dependent on the second control parameter set and are generally not temporally constant, and as a result both the parameters of the first control parameter set and also the parameters of the second control parameter set should always be monitored and readjusted to bring about a reduction in the disturbing influences.

With respect to the prior art, reference is made to EP 2 256 779 B1.

### SUMMARY OF THE INVENTION

The system described herein is a particle beam device with which disturbing influences by units of the particle beam device providing a first particle beam on a second particle beam are reduced or avoided and with which imaging and/or analyzing the object with a differentiation according to interaction particles arising from an interaction of an object with the first particle beam or from an interaction of the object with the second particle beam is/are made possible.

The system described herein serves for imaging, processing and/or analyzing an object using a particle beam device. The particle beam device includes a first particle beam with first charged particles and a second particle beam with second charged particles. By way of example, the first particle beam is generated by at least one first particle beam generator of the particle beam device. By way of example, the second particle beam is furthermore generated by at least one second particle beam generator of the particle beam device. In particular, provision is made for the first particle beam to include electrons or ions. In particular, provision is furthermore made for the second particle beam to include electrons or ions.

The system described herein includes guiding the first particle beam over the object using a first deflection device. In other words, the first particle beam is scanned over the object using the first deflection device. Consequently, the first deflection device includes for example a first scanning device. The first deflection device is controlled by a first control unit. For this purpose, the first deflection device is connected to the first control unit for example for the transmission of signals. In particular, provision is made for the first deflection device to be conductively and/or wirelessly connected to the first control unit. When guiding the first particle beam over the object, processing of the object with the first particle beam and/or detection of first interaction particles and/or a first interaction radiation using at least one detector of the particle beam device is/are performed. The first interaction particles and/or the first interaction radiation results/result from an interaction of the object with the first particle beam. The first interaction particles are, for example, secondary particles emitted by the object, in particular secondary electrons, and/or backscattered particles, in particular backscattered electrons. By way of example, the first interaction radiation is x-ray radiation and/or cathodoluminescence. Detection signals that are generated by the detector on account of first interaction particles being detected are used for example to generate an image of the object. The image is displayed in particular on a display unit of the particle beam device. Detection signals that are generated by the detector on account of the first interaction radiation being detected are used for example to display a result of an analysis of the object.

Even while the first particle beam is guided over the object, a second deflection device is controlled for guiding the second particle beam over the object using a second control unit such that the second particle beam is positionable at a first specifiable location on the object. Here, a specifiable location on the object described herein is understood to mean a well-defined location on the object specified by coordinates. The first specifiable location on the object is a location starting from which the second particle beam is intended to be guided over the object. The second deflection device is controlled by a second control unit. For this purpose, the second deflection device is connected to the second control unit for example for the transmission of signals. In particular, provision is made for the second deflection device to be conductively and/or wirelessly connected to the second control unit.

When the second particle beam is positionable at the first specifiable location on the object using the second deflection device (in other words, when the second deflection device has been brought, after a specific switching time after the start of the controlling effected using the second control unit, into a switching state such that the second particle beam is positionable at the first specifiable location on the object using the second deflection device), the first particle beam is deflected from the object to a second specifiable location using a first deflection unit. The second specifiable location is in particular specified by coordinates. For example, the second specifiable location is a location in the particle beam device that is not arranged on the object, and as a result the first particle beam guided onto the second specifiable location does not interact with the object. As an alternative, the second specifiable location is, for example, a location on the object that has already been imaged, processed and/or analyzed. In particular, the first deflection unit is embodied in the form of an electrostatic and/or magnetic deflection unit.

Provision is made in the system described herein for the second particle beam to be deflected from a third specifiable location to the first specifiable location on the object using a second deflection unit only when the first particle beam has been deflected to the second specifiable location, or only when the first particle beam has reached the second specifiable location. The third specifiable location is in particular specified by coordinates. For example, the third specifiable location is a location in the particle beam device that is not arranged on the object, and as a result the second particle beam guided onto the third specifiable location does not interact with the object. As an alternative, the third specifiable location is, for example, a location on the object that has already been imaged, processed and/or analyzed. In particular, the second deflection unit is embodied in the form of an electrostatic and/or magnetic deflection unit.

From the first specifiable location on the object, the second particle beam is guided over the object using the second deflection device. In other words, the second particle beam is scanned over the object using the second deflection device. Consequently, the second deflection device includes for example a second scanning device. While the second particle beam is guided from the first specifiable location on the object over the object using the second deflection device, the object is processed using the second particle beam and/or second interaction particles and/or a second interaction radiation are/is detected using the detector, where the second interaction particles and/or the second interaction radiation results/result from an interaction of the second particle beam with the object. The second interaction particles are, for example, secondary particles emitted by the object, in particular secondary electrons, and/or backscattered particles, in particular backscattered electrons. By way of example, the second interaction radiation is x-ray radiation and/or cathodoluminescence. Detection signals that are generated by the detector on account of second interaction particles being detected are used for example to generate an image of the object. The image is displayed in particular on a display unit of the particle beam device. Detection signals that are generated by the detector on account of the second interaction radiation being detected are used for example to display a result of an analysis of the object.

The first deflection device and the first deflection unit are, for example, different structural units. In one embodiment of the system described herein, the first deflection device and the first deflection unit are assigned to a first deflection system and part of the first deflection system. In a further embodiment, the first deflection device and the first deflection unit are formed by a single unit.

The second deflection device and the second deflection unit are, for example, different structural units. In one embodiment of the system described herein, the second deflection device and the second deflection unit are assigned to a second deflection system and part of the second deflection system. In a further embodiment, the second deflection device and the second deflection unit are formed by a single unit.

The system described herein has the advantage that controlling the second deflection device for guiding the second particle beam over the object already begins while the first particle beam is still being guided over the object. When the second deflection device has been brought, after a specific switching time after the start of the controlling effected using the second control unit, into a switching state such that the second particle beam is positionable at the first specifiable location on the object using the second deflection device, the first particle beam is deflected from the object to a second specifiable location using the first deflection unit. Basically, images of the object are recorded, an analysis about the object is created and/or the object is processed using the first particle beam until the second deflection unit is set such that the second particle beam is positionable at the first specifiable location on the object. Only then is the first particle beam guided away from the object using the first deflection unit and the second particle beam is positioned at the first specifiable location on the object by deflection using the second deflection unit, from where the second particle beam is guided over the object using the second deflection device. To this extent, no pauses, or only slight pauses, during the processing of the object and/or the detection of interaction particles and/or interaction radiation occur during a switchover from the first particle beam to the second particle beam.

This is advantageous in particular if (i) the first deflection unit can be brought into a switching state for deflecting the first particle beam faster than the first deflection device (that is to say the first scanning device) can be brought into a further switching state for guiding the first particle beam over the object, and/or if (ii) the second deflection unit can be brought into a switching state for deflecting the second particle beam faster than the second deflection device (that is to say the second scanning device) can be brought into a further switching state for guiding the second particle beam over the object. In particular, the first deflection device requires for example a few 10 μs to be placed into the further switching state, while the first deflection unit requires for example a few μs. In particular, the second deflection device requires for example a few 10 μs to be placed into the further switching state, while the second deflection unit requires for example a few μs. The system described herein takes into account the existing different times for reaching the switching states and shortens time periods in which the object is not processed, analyzed and/or imaged. Until the switching state for guiding a particle beam has been reached, the other particle beam continues to be guided over the object.

In comparison with the prior art, it is also possible to provide faster recordings of images of the object, faster analyses of the object and/or faster processing of the object. The processing, the analysis and/or the imaging of the object take place only after the first particle beam has been deflected such that the first particle beam is no longer guided onto the object or to a location of the object, with the result that the first particle beam no longer influences the mode of action of the second particle beam. In particular, disturbing influences caused by units of the particle beam device providing the first particle beam on the second particle beam are reduced or avoided. Furthermore, the system described herein enables imaging and/or analyzing the object with a differentiation according to interaction particles arising from an interaction of the object with the first particle beam or from an interaction of the object with the second particle beam.

In one embodiment of the system described herein, provision is additionally or alternatively made to include the following steps: (i) controlling the second deflection device for guiding the second particle beam over the object begins at a first time at which the first particle beam is still being guided over the object, and (ii) the processing of the object using the second particle beam and/or the detection of second interaction particles and/or a second interaction radiation, which results/result from the interaction of the second particle beam with the object, begins at a second time, with the second time occurring temporally later than the first time. By way of example, the second time lies in the range from 0.5 μs to 100 μs, in particular in the range from 5 μs to 80 μs, after the first time. Provision is further made additionally or alternatively for the deflection of the first particle beam from the object to the second specifiable location to begin at a third time, with the third time, on the one hand, occurring temporally later than the first time and with the third time, on the other hand, occurring temporally earlier than the second time. By way of example, the third time lies in the range from 0.5 μs to 100 μs, in particular in the range from 5 μs to 80 μs, after the first time. By way of example, the third time lies in the range from 0.5 μs to 100 μs, in particular in the range from 5 μs to 80 μs, earlier than the second time. The invention is not restricted to all of the aforementioned ranges. Rather, any range suitable for the invention can be selected.

In a further embodiment of the system described herein, provision is additionally or alternatively made for controlling of the first deflection device for guiding the first particle beam over the object using the first control unit to take place even while the second particle beam is still being guided over the object, such that the first particle beam is positionable at a fourth specifiable location on the object. The fourth specifiable location on the object is a location starting from which the first particle beam is intended to be guided over the object. The first deflection device is controlled by the first control unit. When the first particle beam is positionable at the fourth specifiable location on the object using the first deflection device (in other words, when the first deflection device has been brought, after a specific switching time after the start of the controlling effected using the first control unit, into a switching state such that the first particle beam is positionable at the fourth specifiable location on the object using the first deflection device), the second particle beam is deflected from the object to the third specifiable location using the second deflection unit. As mentioned above, the third specifiable location is, for example, a location in the particle beam device that is not arranged on the object, and as a result the second particle beam guided onto the third specifiable location does not interact with the object. As an alternative, the third specifiable location is, for example, a location on the object that has already been imaged, processed and/or analyzed. Provision is made for the first particle beam to be deflected from the second specifiable location to the fourth specifiable location on the object using the first deflection unit only when the second particle beam has been deflected to the third specifiable location, or only when the first particle beam has reached the third specifiable location.

From the fourth specifiable location on the object, the first particle beam is guided over the object using the first deflection device. In other words, the first particle beam is scanned over the object using the first deflection device. While the first particle beam is guided from the fourth specifiable location on the object over the object using the first deflection device, the object is processed using the first particle beam and/or first interaction particles and/or a first interaction radiation are/is detected using the detector, where the first interaction particles and/or the first interaction radiation results/result from an interaction of the first particle beam with the object. The first interaction particles are, for example, secondary particles emitted by the object, in particular secondary electrons, and/or backscattered particles, in particular backscattered electrons. By way of example, the second interaction radiation is x-ray radiation and/or cathodoluminescence. Detection signals that are generated by the detector on account of first interaction particles being detected are used for example to generate an image of the object. The image is displayed in particular on a display unit of the particle beam device. Detection signals that are generated by the detector on account of the first interaction radiation being detected are used for example to display a result of an analysis of the object.

As mentioned above, in yet a further embodiment of the system described herein, provision is additionally or alternatively made to include one of the following steps:
the third specifiable location used is a location in the particle beam device that is not arranged on the object, and as a result the second particle beam guided onto the third specifiable location does not interact with the object. For example, the third specifiable location is arranged at a stop unit for stopping the second particle beam.
the third specifiable location used is a location on the object that has already been imaged, processed and/or analyzed. For example, the third specifiable location is a start of a scan line of a scanning pattern or any arbitrary point of a scanning pattern. The scanning pattern can have any suitable shape. For example, the scanning pattern takes the form of a line pattern, in particular as mutually parallel lines, of a triangular pattern, of a spiral pattern or of a pattern having randomly selected locations.

In yet a further embodiment of the system described herein, provision is additionally or alternatively made for the controlling of the first deflection device for guiding the first particle beam over the object using the first control unit to take place even while the second particle beam is still being guided over the object, such that the first particle beam is positionable at a fourth specifiable location on the object. The fourth specifiable location on the object is a location starting from which the first particle beam is intended to be guided over the object. The first deflection device is controlled by the first control unit. When the first particle beam is positionable at the fourth specifiable location on the object using the first deflection device (in other words, when the first deflection device has been brought, after a specific switching time after the start of the controlling effected using the first control unit, into a switching state such that the first particle beam is positionable at the fourth specifiable location on the object using the first deflection device), the second particle beam is deflected from the object to a fifth specifiable location using the second deflection unit. The fifth specifiable location is in particular specified by coordinates. For example, the fifth specifiable location is a location in the particle beam device that is not arranged on the object, and as a result the second particle beam guided onto the fifth specifiable location does not interact with the object. As an alternative, the fifth specifiable location is, for example, a location on the object that has already been imaged, processed and/or analyzed. Provision is made for the first particle beam to be deflected from the second specifiable location to the fourth specifiable location on the object using the first deflection unit only when the second particle beam has been deflected to the fifth specifiable location, or only when the first particle beam has reached the fifth specifiable location.

From the fourth specifiable location on the object, the first particle beam is guided over the object using the first deflection device. In other words, the first particle beam is scanned over the object using the first deflection device. While the first particle beam is guided from the fourth specifiable location on the object over the object using the first deflection device, the object is processed using the first particle beam and/or first interaction particles and/or a first interaction radiation are/is detected using the detector, wherein the first interaction particles and/or the first interaction radiation results/result from an interaction of the first particle beam with the object. The first interaction particles are, for example, secondary particles emitted by the object, in particular secondary electrons, and/or backscattered particles, in particular backscattered electrons. By way of example, the second interaction radiation is x-ray radiation and/or cathodoluminescence. Detection signals that are generated by the detector on account of first interaction particles being detected are used for example to generate an image of the object.

The image is displayed in particular on a display unit of the particle beam device. Detection signals that are generated by the detector on account of the first interaction radiation being detected are used for example to display a result of an analysis of the object.

As mentioned above, in one embodiment of the system described herein, provision is additionally or alternatively made for one of the following steps:
the fifth specifiable location used is a location in the particle beam device that is not arranged on the object, and as a result the second particle beam guided onto the fifth specifiable location does not interact with the object. For example, the fifth specifiable location is arranged at a stop unit for stopping the second particle beam.
the fifth specifiable location used is a location on the object that has already been imaged, processed and/or analyzed. For example, the fifth specifiable location is a start of a scan line of a scanning pattern or any arbitrary point of a scanning pattern. The scanning pattern can have any suitable shape. For example, the scanning pattern takes the form of a line pattern, in particular as mutually parallel lines, of a triangular pattern, of a spiral pattern or of a pattern having randomly selected locations.

In one embodiment of the system described herein, provision is additionally or alternatively made to include the following steps: (i) controlling the first deflection device for guiding the first particle beam over the object begins at a fourth time at which the second particle beam is still being guided over the object, and (ii) the processing of the object using the first particle beam and/or the detection of first interaction particles and/or a first interaction radiation, which results/result from the interaction of the first particle beam with the object, begins at a fifth time, with the fifth time occurring temporally later than the fourth time. By way of example, the fifth time lies in the range from 0.5 μs to 100 μs, in particular in the range from 5 μs to 80 μs, after the fourth time. Provision is further made additionally or alternatively for the deflection of the second particle beam from the object to the third specifiable location or the fifth specifiable location to begin at a sixth time, with the sixth time, on the one hand, occurring temporally later than the fourth time and with the sixth time, on the other hand, occurring temporally earlier than the fifth time. By way of example, the fifth time lies in the range from 0.5 μs to 100 μs, in particular in the range from 5 μs to 80 μs, after the fourth time. Furthermore, the sixth time lies in the range from 0.5 μs to 100 μs, in particular in the range from 5 μs to 80 μs, earlier than the fifth time. The invention is not restricted to all of the aforementioned ranges. Rather, any range which is suitable for the invention can be used for the invention.

In a further embodiment of the system described herein, provision is additionally or alternatively made for one of the following steps:
the second specifiable location used is a location in the particle beam device that is not arranged on the object, and as a result the first particle beam guided onto the second specifiable location does not interact with the object. For example, the first specifiable location is arranged at a stop unit for stopping the second particle beam.
the second specifiable location used is a location on the object that has already been imaged, processed and/or analyzed. For example, the second specifiable location is a start of a scan line of a scanning pattern or any arbitrary point of a scanning pattern. The scanning pattern can have any suitable shape. For example, the scanning pattern takes the form of a line pattern, in particular as mutually parallel lines, of a triangular pattern, of a spiral pattern or of a pattern having randomly selected locations.

In yet a further embodiment of the system described herein, provision is additionally or alternatively made for signals for guiding the first particle beam and also the second particle beam to be transmitted between the first control unit and the second control unit. In addition or as an alternative thereto, provision is made for the first control unit to be embodied as a first microprocessor and/or for the second control unit to be embodied as a second microprocessor. In particular, provision is made for the first control unit to be connected to the second control unit for the transmission of signals. For example, provision is made for the first control unit to be conductively and/or wirelessly connected to the second control unit. In a further embodiment of the system described herein, provision is additionally or alternatively made for the first deflection unit to be controlled with the first control unit and/or for the second deflection unit to be controlled with the second control unit. Signals for deflecting the first particle beam and the second particle beam are transmitted between the first control unit and the second control unit.

In yet a further embodiment of the system described herein, provision is additionally or alternatively made for the first control unit and the second control unit to be identical and to form an individual control unit. Both the first deflection unit and also the second deflection unit are controlled, for example, with the individual control unit. For example, the individual control unit is embodied in the form of a microprocessor.

In one embodiment of the system described herein, provision is additionally or alternatively made for an electron beam or an ion beam to be used as the first particle beam. Provision is additionally or alternatively made for an electron beam or an ion beam to be used as the second particle beam.

The system described herein also relates to a computer program product that includes a program code which is loadable or loaded into a processor, in particular a processor of a particle beam device, where the program code, when executed in the processor, controls the particle beam device in such a way that a method having at least one of the aforementioned or following features or having a combination of at least two of the aforementioned or following features is carried out.

The system described herein further relates to a particle beam device for imaging, processing and/or analyzing an object. By way of example, the object is arranged in a sample chamber of the particle beam device.

The particle beam device includes at least one first beam generator for generating a first particle beam with first charged particles. By way of example, the charged particles are electrons or ions. Furthermore, the particle beam device is provided with at least one first objective lens for focusing the first particle beam onto the object. Moreover, the particle beam device includes at least one first deflection device for guiding the particle beam over the object. For example, the first deflection device includes a first scanning device for scanning the first particle beam over the object. Moreover, the particle beam device includes at least one first control unit for controlling the first deflection device. For this purpose, the first deflection device is connected to the first control unit for example for the transmission of signals. In particular, provision is made for the first deflection device to be conductively and/or wirelessly connected to the first control unit. Furthermore, the particle beam device has in particular at least one first deflection unit for deflecting the first particle beam. For example, the first deflection unit is embodied in the form of an electrostatic and/or magnetic deflection unit.

The particle beam device also includes at least one second beam generator for generating a second particle beam with second charged particles. By way of example, the charged particles are electrons or ions. Furthermore, the particle beam device is provided with at least one second objective lens for focusing the second particle beam onto the object. Moreover, the particle beam device includes at least one second deflection device for guiding the second particle beam over the object. For example, the second deflection device includes a second scanning device for scanning the second particle beam over the object. Moreover, the particle beam device includes at least one second control unit for controlling the second deflection device. For this purpose, the second deflection device is connected to the second control unit for example for the transmission of signals. In particular, provision is made for the second deflection device to be conductively and/or wirelessly connected to the second control unit. Furthermore, the particle beam device has in particular at least one second deflection unit for deflecting the second particle beam. For example, the second deflection unit is embodied in the form of an electrostatic and/or magnetic deflection unit.

Further, the particle beam device according to the system described herein is provided with at least one detector for detecting interaction particles and/or interaction radiation, which result/results from an interaction of the first particle beam and/or the second particle beam with the object. Additionally, the particle beam device according to the system described herein is provided with at least one display device for displaying an image and/or a result of an analysis of the object. Moreover, the particle beam device according to the system described herein includes at least one control unit with a processor, into which an aforementioned computer program product has been loaded.

The first deflection device and the first deflection unit are, for example, different structural units. In one embodiment of the system described herein, the first deflection device and the first deflection unit are assigned to a first deflection system and part of the first deflection system. In a further embodiment, the first deflection device and the first deflection unit are formed by a single unit.

The second deflection device and the second deflection unit are, for example, different structural units. In one embodiment of the system described herein, the second deflection device and the second deflection unit are assigned to a second deflection system and part of the second deflection system. In a further embodiment, the second deflection device and the second deflection unit are formed by a single unit.

In a further embodiment of the particle beam device according to the system described herein, provision is made for the first deflection unit to be connected to the first control unit. For example, the first deflection unit is connected to the first control unit for the transmission of signals. In particular, provision is made for the first deflection unit to be conductively and/or wirelessly connected to the first control unit. Additionally or as an alternative thereto, provision is made for the second deflection unit to be connected to the second control unit. For example, the second deflection unit is connected to the second control unit for the transmission of signals. In particular, provision is made for the second deflection unit to be conductively and/or wirelessly connected to the second control unit. Again, in addition or as an alternative thereto, provision is made for the first control unit and the second control unit to form an individual control unit. For example, the individual control unit is embodied in the form of a microprocessor.

In yet a further embodiment of the particle beam device according to the system described herein, provision is made for the particle beam device to be an electron beam device and/or an ion beam device.

### BRIEF DESCRIPTION OF DRAWINGS

The system described herein will be explained in more detail below on the basis of embodiments using drawings, in which:

FIG. 1 shows a schematic illustration of an embodiment of a particle beam device;

FIG. 2 shows the particle beam device according to FIG. 1 in a further schematic illustration;

FIG. 3 shows a schematic illustration of a flowchart of an embodiment of the method according to the system described herein;

FIG. 4 shows a schematic illustration of a control voltage as a function of time for deflection devices of a particle beam device; and

FIG. 5 shows a schematic illustration of additional method steps of the embodiment of the method according to the system described herein according to FIG. 3.

### DETAILED DESCRIPTION OF VARIOUS EMBODIMENTS

The system described herein will now be explained in more detail using a particle beam device in the form of a combination device having an electron beam column and an ion beam column. Express reference is made to the fact that the invention can be used in any particle beam device, in particular in any electron beam device and/or any ion beam device.

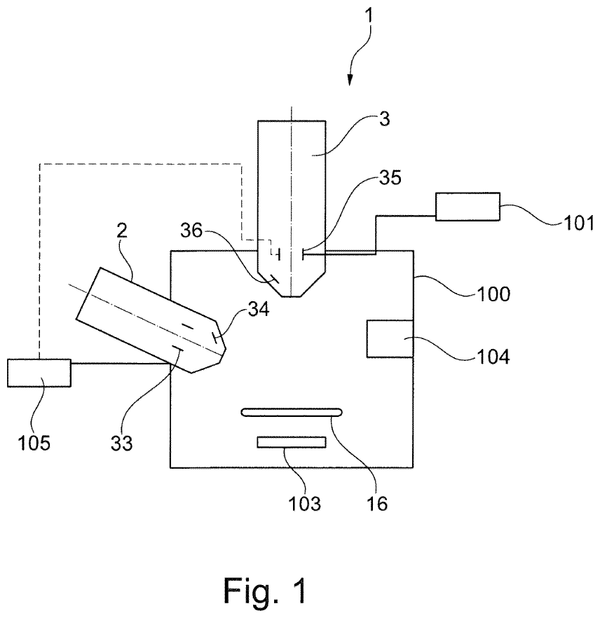

FIG. 1 shows a schematic illustration of an embodiment of a particle beam device 1 according to the system described herein. The particle beam device 1 has a first particle beam column 2 in the form of an ion beam column and a second particle beam column 3 in the form of an electron beam column. The first particle beam column 2 and the second particle beam column 3 are arranged at a sample chamber 100 in which an object 16 to be examined and/or processed is arranged.

Express mention is made here of the fact that the invention is not limited to the first particle beam column 2 being embodied in the form of an ion beam column and the second particle beam column 3 being embodied in the form of an electron beam column. Rather, the invention also makes provision for the possibility of the first particle beam column 2 being embodied in the form of an electron beam column and the second particle beam column 3 being embodied as an ion beam column. According to a further embodiment of the system described herein, both the first particle beam column 2 and also the second particle beam column 3 are embodied in each case in the form of an ion beam column or in each case as an electron beam column.

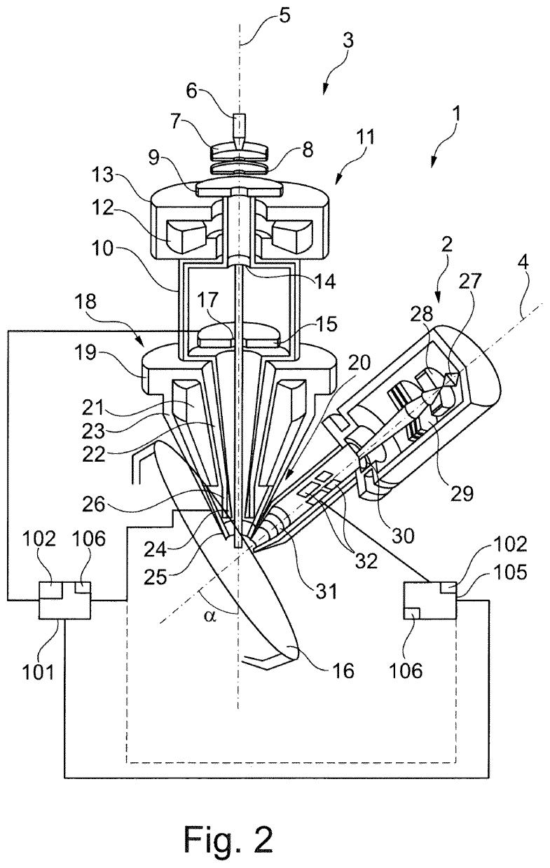

FIG. 2 shows the particle beam device 1 of FIG. 1 in a more detailed illustration. For the sake of clarity, the sample chamber 100 is not illustrated.

The first particle beam column 2 in the form of the ion beam column has a first optical axis 4. Furthermore, the second particle beam column 3 in the form of the electron beam column has a second optical axis 5. The first particle beam column 2 is arranged at an angle with respect to the second particle beam column 3. The angle can lie, for example, in a range of 50° to 90°. However, the invention is not restricted to an angle in the aforementioned range. Rather, any suitable value may be chosen for the angle.

In the following text, reference is made first to the second particle beam column 3 in the form of the electron beam column. The second particle beam column 3 has a second beam generator 6, a first electrode 7, a second electrode 8, and a third electrode 9. The first electrode 7 has the function of a suppressor electrode, while the second electrode 8 has the function of an extractor electrode. The third electrode 9 is an anode and at the same time forms an end of a beam guiding tube 10. A second particle beam in the form of an electron beam is generated using the second beam generator 6. Electrons emerging from the second beam generator 6 are accelerated due to a potential difference between the second beam generator 6 and the third electrode 9 to anode potential, for example ranging from 1 kV to 30 kV. The second particle beam in the form of the electron beam passes through the beam guiding tube 10 and is focused onto the object 16 to be examined. This is discussed in more detail further below.

The beam guiding tube 10 extends through a collimator unit 11, which has a first ring coil 12 and a yoke 13. Following the collimator unit 11, viewed from the second beam generator 6 toward the object 16, a pinhole aperture unit 14 and a first detector 15 having a central opening 17 in the beam guiding tube 10 are arranged along the second optical axis 5. Then, the beam guiding tube 10 extends through a hole in a second objective lens 18. The second objective lens 18 serves for focusing the second particle beam in the form of the electron beam onto the object 16. For this purpose, the second objective lens 18 has a magnetic lens 19 and an electrostatic lens 20. The magnetic lens 19 is provided with a second ring coil 21, an inner pole piece 22, and an outer pole piece 23. The electrostatic lens 20 includes an end 24 of the beam guiding tube 10 and a terminating electrode 25. The end 24 of the beam guiding tube 10 and the terminating electrode 25 form an electrostatic retardation device. The end 24 of the beam guiding tube 10 is, together with the beam guiding tube 10, at anode potential, while the terminating electrode 25 and the object 16 are at a lower potential than the anode potential. In this manner, the electrons of the second particle beam in the form of the electron beam can be decelerated to a desired energy which is desired for examining or imaging the object 16. The second particle beam column 3 additionally has a second deflection device, which includes a second scanning device 26 or is designed as the second scanning device 26, with which the second particle beam in the form of the electron beam can be deflected and scanned over the object 16.

The second particle beam column 3 furthermore has a second deflection unit 35 for deflecting the second particle beam in the form of the electron beam (cf. FIG. 1). For example, the second deflection unit 35 is embodied in the form of an electrostatic and/or magnetic deflection unit. Additionally, the second particle beam column 3 is provided with a second stop unit 36 for stopping the second particle beam in the form of the electron beam (cf. FIG. 1). The second particle beam in the form of the electron beam is deflectable using the second deflection unit 35 for example onto a specifiable location, onto the second stop unit 36, or onto the object 16.

For imaging purposes, secondary electrons and/or backscattered electrons which arise from the interaction of the second particle beam in the form of the electron beam with the object 16 are detected using the first detector 15 arranged in the beam guiding tube 10. The detector signals generated by the first detector 15 are transmitted for imaging purposes to a second control unit 101. The second control unit 101 is also connected to the second scanning device 26. The second control unit 101 controls the speed and the direction with which the second particle beam in the form of the electron beam is scanned over the object 16. Furthermore, the second control unit 101 is connected to the second deflection unit 35 (cf. FIG. 1). The second deflection unit 35 is controlled using the second control unit 101 such that the second particle beam in the form of the electron beam is deflected for example onto a specifiable location, onto the second stop unit 36, or onto the object 16.

The object 16 is arranged on a sample carrier (not illustrated) with which the object 16 is arranged so as to be movable in three mutually perpendicular axes (specifically an x-axis, a y-axis, and a z-axis). Additionally, the sample carrier can be rotated about two rotational axes which are arranged perpendicular to one another. It is possible in this way to bring the object 16 into a desired position.

As mentioned above, the reference sign 2 denotes the first particle beam column in the form of the ion beam column. The first particle beam column 2 has a first beam generator 27 in the form of an ion source. The first beam generator 27 is used to generate a first particle beam in the form of an ion beam. The first particle beam column 2 is furthermore provided with an extraction electrode 28 and a collimator 29. A variable aperture unit 30 is connected downstream of the collimator 29 along the first optical axis 4 in the direction of the object 16. The first particle beam in the form of the ion beam is focused onto the object 16 using a first objective lens 31 in the form of focusing lenses. A first deflection device, which includes a first scanning device 32 or is embodied in the form of the first scanning device 32, is provided to scan the first particle beam in the form of the ion beam over the object 16.

The first particle beam column 2 furthermore has a first deflection unit 33 for deflecting the first particle beam in the form of the ion beam (cf. FIG. 1). For example, the first deflection unit 33 is embodied in the form of an electrostatic and/or magnetic deflection unit. Additionally, the first particle beam column 2 is provided with a first stop unit 34 for stopping the first particle beam in the form of the ion beam (cf. FIG. 1). The first particle beam in the form of the ion beam is deflectable using the first deflection unit 33 for example onto a specifiable location, onto the first stop unit 34, or onto the object 16.

The first scanning device 32 is connected to a first control unit 105. The first control unit 105 controls the speed and the direction with which the first particle beam in the form of the ion beam is scanned over the object 16. Furthermore, the first control unit 105 is connected to the first deflection unit 33 (cf. FIG. 1). The first deflection unit 33 is controlled using the first control unit 105 such that the first particle beam is deflected for example onto a specifiable location, onto the first stop unit 34, or onto the object 16.

The first control unit 105 and the second control unit 101 are connected to each other. Signals for guiding and/or deflecting the first particle beam in the form of the ion beam and the second particle beam in the form of the electron beam are transmitted between the first control unit 105 and the second control unit 101. In a further embodiment, the first control unit 105 is connected to the second scanning device 26. The connection between the first control unit 105 and the second scanning device 26 is illustrated in dashes in FIG. 2. Additionally, provision is made in a further embodiment for the first control unit 105 to be connected to the second deflection unit 35 (illustrated in dashes in FIG. 1). In the embodiment of FIG. 2, the first control unit 105 additionally also controls the speed and the direction with which the second particle beam in the form of the electron beam is scanned and/or deflected over the object 16.

When the first particle beam in the form of the ion beam is incident on the object 16, the first particle beam in the form of the ion beam begins interacting with the material of the object 16. For example, the material of the object 16 is ablated or material is applied to the object 16 while a gas is being supplied. Furthermore, secondary electrons are generated, for example, which are detected using the first detector 15.

The particle beam device 1 includes, in addition to the first detector 15, a further detector, specifically the second detector 103 (cf. FIG. 1). The second detector 103 is arranged in the sample chamber 100, specifically along the second optical axis 5 downstream of the object 16 in the beam direction viewed from the second beam generator 6 toward the object 16. The second detector 103 is used to detect particles transmitted through the object 16 or scattered particles of the second particle beam in the form of the electron beam. The second detector 103 generates detection signals which are fed to the second control unit 101 or to the first control unit 105 for further processing.

Moreover, a third detector in the form of a radiation detector 104 is arranged in the sample chamber 100. The radiation detector 104 is used to detect interaction radiation arising from an interaction of the second particle beam in the form of the electron beam and/or of the first particle beam in the form of the ion beam with the material of the object 16. For example, the interaction radiation is x-ray radiation, which is used in particular for x-ray spectroscopy. Furthermore, the interaction radiation is cathodoluminescence, for example.

The first control unit 105 and/or the second control unit 101 have/has a processor 102. A computer program product having a program code which, when executed in the processor 102, controls the particle beam device 1 such that the particle beam device 1 carries out the method steps of the method according to the system described herein, is loaded in the processor 102. This is explained in more detail further below.

The first control unit 105 has a display device 106, which is used for displaying generated images of the object 16 and/or generated analyses about the object 16. In addition or as an alternative thereto, the display device 106 is arranged at the second control unit 101.

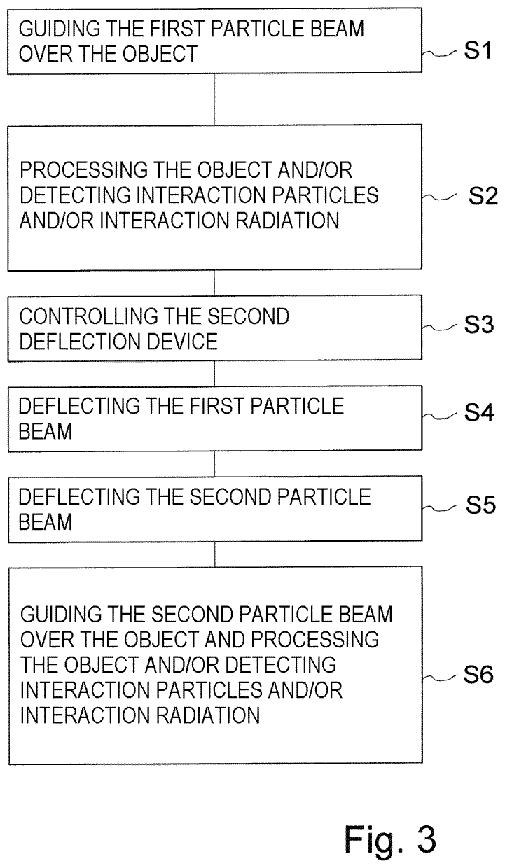

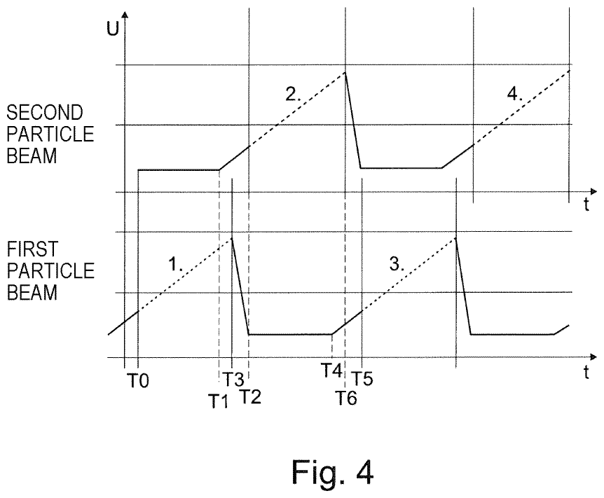

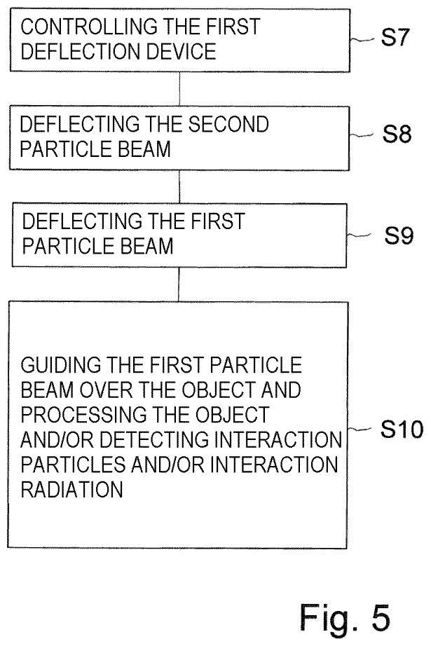

An embodiment of the method according to the system described herein is explained below with reference to FIGS. 3 to 5. FIG. 3 shows a flowchart of the embodiment of the method according to the system described herein. FIG. 4 shows a schematic illustration of a control voltage U of the first scanning device 32 for the first particle beam in the form of the ion beam and of the second scanning device 26 for the second particle beam in the form of the electron beam as a function of time t. FIG. 4 shows four sequences of the method according to the system described herein, as explained in more detail below. FIG. 5 shows further method steps of an embodiment of the system described herein.

In a method step S1, in a first sequence of the method according to the system described herein, the first particle beam in the form of the ion beam is guided over the object 16 using the first scanning device 32. In other words, the first particle beam in the form of the ion beam is scanned over the object 16 using the first scanning device 32. The first scanning device 32 is controlled by the first control unit 105. For this purpose, the first scanning device 32 is connected to the first control unit 105 for example for the transmission of signals. In particular, provision is made for the first scanning device 32 to be conductively and/or wirelessly connected to the first control unit 105.

In a method step S2, while the first particle beam in the form of the ion beam is guided over the object 16, the object 16 is processed using the first particle beam in the form of the ion beam. Provision is additionally or alternatively made for first interaction particles and/or a first interaction radiation which arise/arises from an interaction of the first particle beam in the form of the ion beam with the object 16 to be detected with the first detector 15, with the second detector 103, or the radiation detector 104. The first interaction particles are, for example, secondary electrons emitted by the object 16. By way of example, the first interaction radiation is x-ray radiation and/or cathodoluminescence. The object 16 is processed in a time period between a time T0 and a third time T3 (cf. FIG. 4). At time T0, the second particle beam in the form of the electron beam is deflected to a third specifiable location using the second deflection unit 35. For example, the third specifiable location is a location in the particle beam device 1 that is not arranged on the object 16, and as a result the second particle beam in the form of the electron beam which is guided onto the third specifiable location does not interact with the object 16. The third specifiable location is located for example at the second stop unit 36, which is arranged in the particle beam device 1. The second particle beam in the form of the electron beam does not interact with the object 16 at the third specifiable location. As an alternative, the third specifiable location is, for example, a location on the object 16 that has already been imaged, processed and/or analyzed. For example, the third specifiable location is a start of a scan line of a scanning pattern or any arbitrary point of a scanning pattern. The scanning pattern can have any suitable shape. For example, the scanning pattern takes the form of a line pattern, in particular as mutually parallel lines, of a triangular pattern, of a spiral pattern or of a pattern having randomly selected locations.

Even while the first particle beam in the form of the ion beam is guided over the object 16, controlling of the second scanning device 26 for guiding the second particle beam in the form of the electron beam over the object 16 using the second control unit 101 takes place such that the second particle beam in the form of the electron beam is positionable at a first specifiable location on the object 16. The first specifiable location on the object 16 is a location starting from which the second particle beam in the form of the electron beam is intended to be guided over the object 16. For this purpose, the second scanning device 26 is connected to the second control unit 101 for example for the transmission of signals. In particular, provision is made for the second scanning device 26 to be conductively and/or wirelessly connected to the second control unit 101.

When the second particle beam in the form of the electron beam is positionable at the first specifiable location on the object 16 using the second scanning device 26 (in other words, when the second scanning device 26 has been brought, after a specific switching time after the start of the controlling effected using the second control unit 101, into a switching state such that the second particle beam in the form of the electron beam is positionable at the first specifiable location on the object 16 using the second scanning device 26), the first particle beam in the form of the ion beam is deflected in a method step S4 from the object 16 to a second specifiable location using the first deflection unit 33. For example, the second specifiable location is a location in the particle beam device 1 that is not arranged on the object 16, and as a result the first particle beam in the form of the ion beam which is guided onto the second specifiable location does not interact with the object 16. The second specifiable location is located for example at the first stop unit 34, which is arranged in the particle beam device 1. The second particle beam in the form of the ion beam does not interact with the object 16 at the second specifiable location. As an alternative, the second specifiable location is, for example, a location on the object 16 that has already been imaged, processed and/or analyzed. For example, the second specifiable location is a start of a scan line of a scanning pattern or any arbitrary point of a scanning pattern. The scanning pattern can have any suitable shape. For example, the scanning pattern takes the form of a line pattern, in particular as mutually parallel lines, of a triangular pattern, of a spiral pattern or of a pattern having randomly selected locations.

Provision is made in the method step S5 for the second particle beam in the form of the electron beam to be deflected from the third specifiable location to the first specifiable location on the object using the second deflection unit 35 only when the first particle beam in the form of the ion beam has been deflected to the second specifiable location, or only when the first particle beam in the form of the ion beam has reached the second specifiable location. For example, as explained above, the third specifiable location is a location in the particle beam device 1 that is not arranged on the object 16, and as a result the second particle beam in the form of the electron beam which is guided onto the third specifiable location does not interact with the object 16. The third specifiable location is located for example at the second stop unit 36, which is arranged in the particle beam device 1. As an alternative, the third specifiable location is, for example, a location on the object 16 that has already been imaged, processed and/or analyzed. For example, the third specifiable location is a start of a scan line of a scanning pattern or any arbitrary point of a scanning pattern. The scanning pattern can have any suitable shape. For example, the scanning pattern takes the form of a line pattern, in particular as mutually parallel lines, of a triangular pattern, of a spiral pattern or of a pattern having randomly selected locations.

From the first specifiable location on the object 16, the second particle beam in the form of the electron beam is guided over the object 16 using the second scanning device 26. In other words, the second particle beam in the form of the electron beam is scanned over the object 16 using the second scanning device 26. While the second particle beam in the form of the electron beam is guided from the first specifiable location on the object 16 over the object 16 using the second scanning device 26, the object 16 is processed using the second particle beam in the form of the electron beam and/or second interaction particles and/or a second interaction radiation are/is detected using the first detector 15, the second detector 103, or the radiation detector 104. The second interaction particles and/or the second interaction radiation result/results from an interaction of the second particle beam in the form of the electron beam with the object 16. The second interaction particles are, for example, secondary particles emitted by the object 16, in particular secondary electrons, and/or backscattered particles, in particular backscattered electrons. By way of example, the second interaction radiation is x-ray radiation and/or cathodoluminescence. Detection signals that are generated by the detector 15 or 103 on account of second interaction particles being detected are used for example to generate an image of the object 16. The image is displayed in particular on the display device 106 of the particle beam device 1. Detection signals that are generated by the radiation detector 104 on account of the second interaction radiation being detected are used for example to display a result of an analysis of the object 16.

The controlling of the second scanning device 26 for guiding the second particle beam in the form of the electron beam over the object begins at a first time T1, at which the first particle beam in the form of the ion beam is still being guided over the object 16 (cf. FIG. 4). Furthermore, the processing of the object 16 using the second particle beam in the form of the electron beam and/or the detection of second interaction particles and/or a second interaction radiation, which result/results from the interaction of the second particle beam in the form of the electron beam with the object 16, begins/begin at a second time T2, with the second time T2 occurring temporally later than the first time T1. By way of example, the second time T2 lies in the range from 0.5 μs to 100 μs, in particular in the range from 5 μs to 80 μs, after the first time T1. Provision is further made for the deflection of the first particle beam in the form of the ion beam from the object 16 to the second specifiable location to begin at a third time T3, with the third time T3, on the one hand, occurring temporally later than the first time T1 and with the third time T3, on the other hand, occurring temporally earlier than the second time T2. By way of example, the third time T3 lies in the range from 0.5 μs to 100 μs, in particular in the range from 5 μs to 80 μs, after the first time T1. Furthermore, the third time T3 lies in the range from 0.5 μs to 100 μs, in particular in the range from 5 μs to 80 μs, earlier than the second time T2. The invention is not restricted to all of the aforementioned ranges. Rather, any range suitable for the invention can be selected.

FIG. 5 shows further method steps of an embodiment of the method according to the system described herein, which for example are carried out after method step S6. Basically, the method steps of FIG. 5 describe a second sequence of the method according to the system described herein. At time T2, the first sequence of the method according to the system described herein ends and the second sequence of the method according to the system described herein begins. Method step S6 is therefore already part of the second sequence.

As explained above, the second particle beam in the form of the electron beam is guided in method step S6 over the object 16 using the second scanning device 26. The object 16 is processed using the second particle beam in the form of the electron beam. In addition or alternatively, the object 16 is imaged and/or analyzed using the second particle beam in the form of the electron beam by detecting the second interaction particles and/or the second interaction radiation. The processing, imaging, and/or the analysing of the object 16 take/takes place in a time period between the second time T2 and a sixth time T6. As explained above, the first particle beam in the form of the ion beam is deflected to the second specifiable location at the second time T2 using the first deflection unit 33.

Even while the second particle beam in the form of the electron beam is guided over the object 16, in method step S7 controlling of the first scanning device 32 for guiding the first particle beam in the form of the ion beam over the object 16 using the first control unit 105 takes place such that the first particle beam in the form of the ion beam is positionable at a fourth specifiable location on the object 16. The fourth specifiable location on the object 16 is a location starting from which the first particle beam in the form of the ion beam is intended to be guided over the object 16. The first scanning device 32 is controlled by the first control unit 105.

When the first particle beam in the form of the ion beam is positionable at the fourth specifiable location on the object 16 using the first scanning device 32 (in other words, when the first scanning device 32 has been brought, after a specific switching time after the start of the controlling effected using the first control unit 105, into a switching state such that the first particle beam in the form of the ion beam is positionable at the fourth specifiable location on the object 16 using the first scanning device 32), the second particle beam in the form of the electron beam is deflected in method step S8 from the object 16 to the third specifiable location using the second deflection unit 35. For example, as explained above, the third specifiable location is a location in the particle beam device 1 that is not arranged on the object 16, and as a result the second particle beam in the form of the electron beam which is guided onto the third specifiable location does not interact with the object 16. As an alternative, the third specifiable location is, for example, a location on the object 16 that has already been imaged, processed and/or analyzed. For example, this third specifiable location is a start of a scan line of a scanning pattern or any arbitrary point of a scanning pattern. The scanning pattern can have any suitable shape. For example, the scanning pattern takes the form of a line pattern, in particular as mutually parallel lines, of a triangular pattern, of a spiral pattern or of a pattern having randomly selected locations.

Provision is made in the method step S9 of the method according to the system described herein for the first particle beam in the form of the ion beam to be deflected from the second specifiable location to the fourth specifiable location on the object 16 using the first deflection unit 33 only when the second particle beam in the form of the electron beam has been deflected to the third specifiable location, or only when the second particle beam in the form of the electron beam has reached the third specifiable location.

From the fourth specifiable location on the object 16, the first particle beam in the form of the ion beam is guided in method step S10 over the object 16 using the first scanning device 32. In other words, the first particle beam in the form of the ion beam is scanned over the object 16 using the first scanning device 32. While the first particle beam in the form of the ion beam is guided from the fourth specifiable location on the object 16 over the object 16 using the first scanning device 32, the object 16 is processed using the first particle beam in the form of the ion beam and/or first interaction particles and/or a first interaction radiation are/is detected using the first detector 15, the second detector 103, or the radiation detector 104. The first interaction particles and/or the first interaction radiation result/results from an interaction of the first particle beam in the form of the ion beam with the object 16. The first interaction particles are, for example, secondary particles, in particular secondary electrons, emitted by the object 16. By way of example, the first interaction radiation is x-ray radiation and/or cathodoluminescence. Detection signals that are generated by the detector 15 or 103 on account of first interaction particles being detected are used for example to generate an image of the object 16. The image is displayed in particular on the display device 106 of the particle beam device 1. Detection signals that are generated by the radiation detector 104 on account of the first interaction radiation being detected are used for example to display a result of an analysis of the object 16.

The controlling of the first scanning device 32 for guiding the first particle beam in the form of the ion beam over the object 16 begins at a fourth time T4, at which the second particle beam in the form of the electron beam is still being guided over the object 16 (cf. FIG. 4). Furthermore, the processing of the object 16 using the first particle beam in the form of the ion beam and/or the detection of first interaction particles and/or a first interaction radiation, which result/results from the interaction of the first particle beam in the form of the ion beam with the object 16, begins/begin at a fifth time T5, with the fifth time T5 occurring temporally later than the fourth time T4. By way of example, the fifth time T5 lies in the range from 0.5 μs to 100 μs, in particular in the range from 5 μs to 80 μs, after the fourth time T4. The deflection of the second particle beam in the form of the electron beam from the object 16 to the third specifiable location begins at a sixth time T6, with the sixth time T6, on the one hand, occurring temporally later than the fourth time T4 and with the sixth time T6, on the other hand, occurring temporally earlier than the fifth time T5. By way of example, the fifth time T5 lies in the range from 0.5 μs to 100 μs, in particular in the range from 5 μs to 80 μs, after the fourth time T4. Furthermore, the sixth time T6 lies in the range from 0.5 μs to 100 μs, in particular in the range from 5 μs to 80 μs, earlier than the fifth time T5. The invention is not restricted to all of the aforementioned ranges. Rather, any range which is suitable for the invention can be used for the invention.

At the fifth time T5, the second sequence of the method according to the system described herein ends and a third sequence of the method according to the system described herein begins, which is followed by a fourth sequence of the method according to the system described herein. Basically, the method steps S1 to S5 are repeated in the third sequence, with the abovementioned times being adapted in accordance with the advanced time t. Furthermore, the method steps S6 to S9 (possibly S10) are basically repeated in the fourth sequence, with the abovementioned times being adapted in accordance with the advanced time t.

The controlling operation according to FIG. 4 basically relates to a scan pattern in the form of a line pattern, for example in the form of mutually parallel lines. It is explicitly mentioned that the scan pattern used can be any suitable scan pattern, in particular also a triangular pattern, a spiral pattern, or a pattern with randomly selected locations.

The system described herein has the advantage that controlling the second deflection device 26 for guiding the second particle beam in the form of the electron beam over the object 16 already begins while the first particle beam in the form of the ion beam is still being guided over the object 16. When the second scanning device 26 has been brought, after a specific switching time after the start of the controlling effected using the second control unit 101, into a switching state such that the second particle beam in the form of the electron beam is positionable at the first specifiable location on the object 16 using the second scanning device 26, the first particle beam in the form of the ion beam is deflected from the object 16 to the second specifiable location using the first deflection unit 33. Basically, images of the object 16 are recorded, an analysis about the object 16 is created and/or the object 16 is processed using the first particle beam in the form of the ion beam until the second scanning device 26 is set such that the second particle beam in the form of the electron beam is positionable at the first specifiable location on the object 16. Only then is the first particle beam in the form of the ion beam guided away from the object 16 using the first deflection unit 33 and the second particle beam in the form of the electron beam is positioned at the first specifiable location on the object 16 by deflection using the second deflection unit 35, from where the second particle beam in the form of the electron beam is guided over the object 16 using the second scanning device 26. What was stated above applies accordingly to controlling the first scanning device 32 for guiding the first particle beam in the form of the ion beam over the object 16 while the second particle beam in the form of the electron beam is still being guided over the object 16. To this extent, no pauses, or only slight pauses, during the processing of the object 16 and/or the detection of interaction particles and/or interaction radiation occur during a switchover from the first particle beam in the form of the ion beam to the second particle beam in the form of the electron beam, and vice versa.

This is advantageous in particular if (i) the first deflection unit 33 can be brought into a switching state for deflecting the first particle beam in the form of the ion beam faster than the first scanning device 32 can be brought into a further switching state for guiding the first particle beam in the form of the ion beam over the object 16, and/or if (ii) the second deflection unit 35 can be brought into a switching state for deflecting the second particle beam in the form of the electron beam faster than the second scanning device 26 can be brought into a further switching state for guiding the second particle beam in the form of the electron beam over the object 16. In particular, the first scanning device 32 requires for example a few 10 μs to be placed into the further switching state, while the first deflection unit 33 requires for example a few μs. Furthermore, the second scanning device 26 requires for example a few 10 μs to be placed into the further switching state, while the second deflection unit 35 requires for example a few μs. The system described herein takes into account the existing different times for reaching the switching states and shortens time periods in which the object 16 is not processed, analyzed and/or imaged. Until the switching state for guiding a particle beam has been reached, the other particle beam continues to be guided over the object 16.

In comparison with the prior art, it is also possible to provide faster recordings of images of the object 16, faster analyses of the object 16 and/or faster processing of the object 16. The processing, the analysis and/or the imaging of the object 16 take/takes place only after the first particle beam in the form of the ion beam has been deflected such that it is no longer guided onto the object 16 or to a location of the object 16, with the result that the first particle beam in the form of the ion beam no longer influences the mode of action of the second particle beam in the form of the electron beam. In particular, disturbing influences caused by units of the particle beam device 1 providing the first particle beam in the form of the ion beam on the second particle beam in the form of the electron beam are reduced or avoided. Furthermore, the system described herein enables imaging and/or analyzing of the object 16 with a differentiation according to interaction particles arising from an interaction of the object 16 with the first particle beam in the form of the ion beam or from an interaction of the object 16 with the second particle beam in the form of the electron beam. It is furthermore advantageous that the processing, the analysis and/or the imaging of the object 16 take/takes place only after the second particle beam in the form of the electron beam has been deflected such that the electron beam is no longer guided onto the object 16 or to a location of the object 16, with the result that the second particle beam in the form of the electron beam no longer influences the mode of action of the first particle beam in the form of the ion beam. The statements made further above also apply here analogously.

Reference is explicitly made to the fact that the method steps explained above are not exclusively performable in the described order. Rather, every order and/or parallel performance of the method steps that is/are suitable for the invention is/are provided by the invention.

The features of the invention disclosed in the present description, in the drawings and in the claims may be essential for the realization of the invention in the various embodiments thereof both individually and in arbitrary combinations. The invention is not restricted to the described embodiments. It can be varied within the scope of the claims and taking into account the knowledge of the relevant person skilled in the art.

1. A method for imaging, processing and/or analyzing an object using a particle beam device having a first particle beam with first charged particles and having a second particle beam with second charged particles, the method comprising:
guiding the first particle beam over the object using a first deflection device, which is controlled by a first control unit;
performing at least one of the following: processing the object using the first particle beam or detecting first interaction particles and/or a first interaction radiation using at least one detector, wherein the first interaction particles and/or the first interaction radiation result/results from an interaction of the first particle beam with the object;
while the first particle beam is guided over the object, controlling a second deflection device for guiding the second particle beam over the object using a second control unit such that the second particle beam is positionable at a first specifiable location on the object;
when the second particle beam is positionable at the first specifiable location on the object using the second deflection device, deflecting the first particle beam from the object to a second specifiable location using a first deflection unit; and
only when the first particle beam has been deflected to the second specifiable location, or only when the first particle beam has reached the second specifiable location, deflecting the second particle beam from a third specifiable location to the first specifiable location on the object using a second deflection unit and guiding the second particle beam from the first specifiable location on the object over the object using the second deflection device, and performing at least one of the following: processing the object using the second particle beam or detecting second interaction particles and/or a second interaction radiation which results/results from an interaction of the second particle beam with the object, using the detector.

2. The method as claimed in claim 1, further comprising:
controlling the second deflection device for guiding the second particle beam over the object beginning at a first time, at which the first particle beam is still being guided over the object; and
processing the object using the second particle beam and/or detecting the second interaction particles and/or the second interaction radiation, which result/results from the interaction of the second particle beam with the object, beginning at a second time, with the second time occurring temporally later than the first time.

3. The method as claimed in claim 2, wherein the deflection of the first particle beam from the object to the second specifiable location begins at a third time, with the third time, on the one hand, occurring temporally later than the first time and with the third time, on the other hand, occurring temporally earlier than the second time.

4. The method as claimed in claim 1, further comprising:
while the second particle beam is guided over the object, controlling the first deflection device for guiding the first particle beam over the object using the first control unit such that the first particle beam is positionable at a fourth specifiable location on the object;
when the first particle beam is positionable at the fourth specifiable location on the object using the first deflection device, deflecting the second particle beam from the object to the third specifiable location using the second deflection unit; and
only when the second particle beam has been deflected to the third specifiable location, or only when the second particle beam has reached the third specifiable location, deflecting the first particle beam from the second specifiable location on the object to the fourth specifiable location on the object using the first deflection unit and guiding the first particle beam from the fourth specifiable location on the object over the object using the first deflection device, and performing at least one of the following: processing the object using the first particle beam or detecting the first interaction particles and/or the first interaction radiation which results/results from the interaction of the first particle beam with the object, using the detector.

5. The method as claimed in claim 4, further comprising at least one of the following:
the third specifiable location used is a location in the particle beam device that is not arranged on the object, and as a result the second particle beam guided onto the third specifiable location does not interact with the object; or
the third specifiable location used is a location on the object that has already been imaged, processed and/or analyzed.

6. The method as claimed in claim 1, further comprising:
while the second particle beam is guided over the object, controlling the first deflection device for guiding the first particle beam over the object using the first control unit such that the first particle beam is positionable at a fourth specifiable location on the object;
when the first particle beam is positionable at the fourth specifiable location on the object using the first deflection device, deflecting the second particle beam from the object to a fifth specifiable location using the second deflection unit; and
only when the second particle beam has been deflected to the fifth specifiable location, or only when the second particle beam has reached the fifth specifiable location, deflecting the first particle beam from the second specifiable location on the object to the fourth specifiable location on the object using the first deflection unit and guiding the first particle beam from the fourth specifiable location on the object over the object using the first deflection device, and performing at least one of the following: processing the object using the first particle beam or detecting the first interaction particles and/or the first interaction radiation which results/results from the interaction of the first particle beam with the object, using the detector.

7. The method as claimed in claim 6, further comprising one of the following:
the fifth specifiable location used is a location in the particle beam device that is not arranged on the object, and as a result the second particle beam guided onto the fifth specifiable location does not interact with the object; or
the fifth specifiable location used is a location on the object that has already been imaged, processed and/or analyzed.

8. The method as claimed in claim 4, further comprising:
controlling the first deflection device for guiding the first particle beam over the object beginning at a fourth time, at which the second particle beam is still being guided over the object; and
processing the object using the first particle beam and/or detecting the first interaction particles and/or the first interaction radiation, which result/results from the interaction of the first particle beam with the object, beginning at a fifth time, with the fifth time occurring temporally later than the fourth time.

9. The method as claimed in claim 8, wherein the deflection of the second particle beam to the third specifiable location or the fifth specifiable location begins at a sixth time, with the sixth time, on the one hand, occurring temporally later than the fourth time and with the sixth time, on the other hand, occurring temporally earlier than the fifth time.

10. The method as claimed in claim 1, further comprising:
the second specifiable location used is a location in the particle beam device that is not arranged on the object, and as a result the first particle beam guided onto the second specifiable location does not interact with the object;
the second specifiable location used is a location on the object that has already been imaged, processed and/or analyzed.

11. The method as claimed in claim 1, further comprising:
transmitting signals for guiding the first particle beam and the second particle beam between the first control unit and the second control unit, wherein; the first deflection unit is controlled with the first control unit, the second deflection unit is controlled with the second control unit, and signals for deflecting the first particle beam and the second particle beam are transmitted between the first control unit and the second control unit.

12. The method as claimed in claim 1, wherein the first control unit and the second control unit are identical and form an individual control unit, and wherein both the first deflection unit and also the second deflection unit are controlled with the individual control unit.

13. The method as claimed in claim 1, wherein: the first particle beam used is an electron beam or an ion beam and/or the second particle beam used is an electron beam or an ion beam.

14. A non-transitory computer readable medium containing program code, which is loadable into a processor and which, when executed, controls a particle beam device to perform the following:
guiding a first particle beam over an object using a first deflection device, which is controlled by a first control unit;
performing at least one of the following: processing the object using the first particle beam or detecting first interaction particles and/or a first interaction radiation using at least one detector, wherein the first interaction particles and/or the first interaction radiation are a result of an interaction of the first particle beam with the object;
while the first particle beam is guided over the object, controlling a second deflection device to guide a second particle beam over the object using a second control unit such that the second particle beam is positionable at a first specifiable location on the object;
when the second particle beam is positionable at the first specifiable location on the object using the second deflection device, deflecting the first particle beam from the object to a second specifiable location using a first deflection unit; and
only when the first particle beam has been deflected to the second specifiable location, or only when the first particle beam has reached the second specifiable location, deflecting the second particle beam from a third specifiable location to the first specifiable location on the object using a second deflection unit and guiding the second particle beam from the first specifiable location on the object over the object using the second deflection device, and performing at least one of the following: processing the object using the second particle beam or detecting second interaction particles and/or a second interaction radiation which results/results from an interaction of the second particle beam with the object, using the detector.

15. A particle beam device for imaging, processing and/or analyzing an object, comprising
at least one first beam generator for generating a first particle beam comprising first charged particles;
at least one first objective lens for focusing the particle beam onto the object;
at least one first deflection device for guiding the first particle beam over the object;
at least one first control unit for controlling the first deflection device;
at least one second beam generator for generating a second particle beam comprising second charged particles;
at least one second objective lens for focusing the particle beam onto the object;
at least one second deflection device for guiding the second particle beam over the object;
at least one second control unit for controlling the second deflection device;
at least one detector for detecting interaction particles and/or interaction radiation resulting from an interaction of the first particle beam and/or the second particle beam with the object;
at least one display device for displaying the image and/or a result of the analysis of the object;
a processor; and
a non-transitory computer readable medium coupled to the processor and containing software which, when executed by the processor, guides the first particle beam over the object using the first deflection device, performs at least one of the following: processes the object using the first particle beam or detects first interaction particles and/or a first interaction radiation using the at least one detector, wherein the first interaction particles and/or the first interaction radiation are a result of an interaction of the first particle beam with the object, while the first particle beam is guided over the object, controls the second deflection device to guide the second particle beam over the object such that the second particle beam is positionable at a first specifiable location on the object, when the second particle beam is positionable at the first specifiable location on the object using the second deflection device, deflects the first particle beam from the object to a second specifiable location using a first deflection unit, and only when the first particle beam has been deflected to the second specifiable location, or only when the first particle beam has reached the second specifiable location, deflects the second particle beam from a third specifiable location to the first specifiable location on the object using a second deflection unit and guides the second particle beam from the first specifiable location on the object over the object using the second deflection device, and performs at least one of the following: processes the object using the second particle beam or detects second interaction particles and/or a second interaction radiation which results/results from an interaction of the second particle beam with the object, using the detector.

16. (canceled)

17. The particle beam device as claimed in claim 15, wherein the particle beam device has at least one of the following features:
the first deflection unit is connected to the first control unit;
the second deflection unit is connected to the second control unit;
the first control unit and the second control unit form an individual control unit.

18. The particle beam device as claimed in claim 15, wherein the particle beam device is an electron beam device and/or an ion beam device.
